(19) United States
(12) Patent Application Publication
(10) Pub. No.: US 2024/0153746 A1
(43) Pub. Date: May 9, 2024

(54) SUBSTRATE PROCESSING APPARATUS

(71) Applicant: ASM IP Holding B.V., Almere (NL)

(72) Inventors: WonKi Jeong, Cheonan-si (KR); Yonjong Jeon, Yongin-si (KR); DongJun Park, Osan-si (KR)

(21) Appl. No.: 18/413,728

(22) Filed: Jan. 16, 2024

Related U.S. Application Data
(63) Continuation of application No. 17/392,259, filed on Aug. 3, 2021.
(60) Provisional application No. 63/062,334, filed on Aug. 6, 2020.

(51) Int. Cl. H01J 37/32

(52) U.S. Cl. CPC H01J 37/32513; H01J 37/3244

(57) ABSTRACT

A substrate processing apparatus having a simplified exhaust structure includes: a substrate supporting unit configured to support a substrate; a first lid on the substrate supporting unit, the first lid including at least one processing unit; a second lid under the first lid, the second lid including a partition wall; and a support arranged under the first lid and the second lid and including an opening and a seating portion on the opening, wherein the second lid is on the seating portion of the support.

### CROSS-REFERENCE TO RELATED APPLICATIONS

This application is a continuation of, and claims priority to, U.S. patent application Ser. No. 17/392,259, filed Aug. 3, 2021 and entitled “SUBSTRATE PROCESSING APPARATUS,” which is a nonprovisional of, and claims priority to, U.S. Provisional Patent Application No. 63/062,334, filed on Aug. 6, 2020 in the United States Patent and Trademark Office, the disclosures of which are incorporated by reference herein.

### BACKGROUND

### 1. Field

One or more embodiments relate to a substrate processing apparatus, and more particularly, to a substrate processing apparatus having a simplified exhaust structure while preventing the generation of parasitic plasma.

### 2. Description of the Related Art

In a semiconductor deposition process, a plasma process may be performed at lower temperature than in a thermal process, thereby reducing thermal shock to a semiconductor device. In addition, a plasma process has been applied to many processes because the durability of a device and the life of components may be improved by applying less thermal shock to a semiconductor deposition device.

In a deposition process using plasma, plasma is generated by applying RF power to a reaction gas supplied to a reaction space and ionizing the reaction gas. The ionized reaction gas is activated to react with a substrate to form a thin film on the substrate. A deposition process using such plasma is disclosed in Korean Patent Publication No. 10-2019-0032077 and Korean Registration No. 10-1680379.

In order to maximize the efficiency of plasma, plasma needs to be formed on a substrate in a reaction space. However, parasitic plasma generated in an area other than the reaction space, such as an exhaust line, causes a decrease in the efficiency of a plasma process in the reaction space.

### SUMMARY

One or more embodiments include a substrate processing apparatus capable of preventing parasitic plasma generated in an area other than a reaction space such as an exhaust space.

One or more embodiments include a substrate processing apparatus capable of preventing the generation of parasitic plasma in an exhaust duct and an exhaust path while simplifying a structure of the exhaust duct.

One or more embodiments include a substrate processing apparatus capable of reducing the possibility of gas leakage to the outside of a reaction space.

Additional aspects will be set forth in part in the description which follows and, in part, will be apparent from the description, or may be learned by practice of the presented embodiments of the disclosure.

According to one or more embodiments, a substrate processing apparatus includes a substrate supporting unit configured to support a substrate; a first lid on the substrate supporting unit, the first lid including at least one processing unit; a second lid under the first lid, the second lid including a partition wall; and a support arranged under the first lid and the second lid and including an opening and a seating portion on the opening, wherein the second lid may be on the seating portion of the support.

According to an example of the substrate processing apparatus, a reaction space may be formed between the substrate supporting unit and the processing unit, and an exhaust space may be formed between the second lid and the support.

According to another example of the substrate processing apparatus, a first surface of the partition wall may define the reaction space, and a second surface of the partition wall may define the exhaust space.

According to another example of the substrate processing apparatus, the exhaust space may be arranged to surround the reaction space, a channel communicating the reaction space and the exhaust space may be formed under the partition wall, and a gas in the reaction space may be exhausted to the outside through the channel, the exhaust space, and the opening.

According to another example of the substrate processing apparatus, the second lid may be detachably fixed to the support.

According to another example of the substrate processing apparatus, the seating portion of the support includes a stepped structure, and the second lid may be arranged to be inserted into the stepped structure.

According to another example of the substrate processing apparatus, the substrate processing apparatus may further include a connector configured to connect the second lid to the support.

According to another example of the substrate processing apparatus, the connector may include a lid portion extending from an upper surface of the support to an upper surface of the second lid, and a portion of the second lid may be arranged to be inserted into a space between the lid portion and the support.

According to another example of the substrate processing apparatus, the connecting portion may include a protrusion extending from the second lid, and the protrusion may be arranged to be inserted into a groove provided in the support.

According to another example of the substrate processing apparatus, the second lid may further include a connecting wall extending from the partition wall and providing a contact surface with the processing unit, and a lower surface of the connecting wall may be arranged to contact an upper surface of the seating portion.

According to another example of the substrate processing apparatus, the substrate processing apparatus may further include a conductive extension arranged to surround a portion of the second lid.

According to another example of the substrate processing apparatus, the conductive extension may be electrically connected to the support, and accordingly, the conductive extension and the support may have the same potential.

According to another example of the substrate processing apparatus, the conductive extension may be arranged to further surround a side surface of the support.

According to another example of the substrate processing apparatus, the conductive extension may be implemented as a metal coating layer on the surface of the second lid.

According to another example of the substrate processing apparatus, the second lid may include a first portion having a first thickness and a second portion having a second thickness greater than the first thickness.

According to another example of the substrate processing apparatus, the conductive extension is arranged to contact the second lid, and the sum of a thickness of the conductive extension and the first thickness may be substantially the same as the second thickness.

According to another example of the substrate processing apparatus, the substrate processing apparatus may further include at least one ring member arranged between the second lid and the support.

According to another example of the substrate processing apparatus, the second lid may include an insulator, and the support may include a conductor.

According to one or more embodiments, a substrate processing apparatus includes a substrate supporting unit configured to support a substrate; a first lid on the substrate supporting unit, the first lid including at least one processing unit; a second lid under the first lid, wherein a reaction space is formed between the substrate supporting unit and the processing unit, and an exhaust space is formed to surround the reaction space, and a first side of the exhaust space may be defined by the exhaust unit, and a second side of the exhaust space may be defined by the support.

According to one or more embodiments, a substrate processing apparatus having an exhaust space includes an exhaust unit defining at least a portion of the exhaust space; a support configured to support the exhaust unit and including a conductor; and a conductive extension arranged to surround a portion of the exhaust unit, wherein the conductive extension, together with the conductor of the support, may be configured to prevent parasitic plasma generated in the exhaust space.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 and 2 are views of a substrate processing apparatus according to embodiments of the inventive concept;

FIG. 3 is a view of a substrate processing apparatus according to other embodiments;

FIG. 4 is a view of a substrate processing apparatus according to other embodiments;

FIG. 5 is a view of a substrate processing apparatus according to other embodiments;

FIGS. 6A and 6B are views of a substrate processing apparatus according to related embodiments;

FIGS. 7 and 8 are views respectively illustrating embodiments of an exhaust duct of the related art and an exhaust duct according to the disclosure;

FIG. 9 is a view illustrating an embodiment of a reactor including the exhaust duct of FIG. 8; and

FIG. 10 is a view of a structure in which a potential difference between an inner lid and a top lid is the same.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments of the disclosure will be described in detail with reference to the accompanying drawings.

In this regard, the present embodiments may have different forms and should not be construed as being limited to the descriptions set forth herein. Rather, these embodiments are provided so that the present disclosure will be thorough and complete, and will fully convey the scope of the present disclosure to one of ordinary skill in the art.

The terminology used herein is for the purpose of describing particular embodiments and is not intended to limit the disclosure. As used herein, the singular forms “a”, “an”, and “the” are intended to include the plural forms as well, unless the context clearly indicates otherwise. It will be further understood that the terms “includes”, “comprises” and/or “including”, “comprising” used herein specify the presence of stated features, integers, steps, processes, members, components, and/or groups thereof, but do not preclude the presence or addition of one or more other features, integers, steps, processes, members, components, and/or groups thereof. As used herein, the term “and/or” includes any and all combinations of one or more of the associated listed items.

It will be understood that, although the terms first, second, etc. may be used herein to describe various members, components, regions, layers, and/or sections, these members, components, regions, layers, and/or sections should not be limited by these terms. These terms do not denote any order, quantity, or importance, but rather are only used to distinguish one component, region, layer, and/or section from another component, region, layer, and/or section. Thus, a first member, component, region, layer, or section discussed below could be termed a second member, component, region, layer, or section without departing from the teachings of embodiments.

Embodiments of the disclosure will be described hereinafter with reference to the drawings in which embodiments of the disclosure are schematically illustrated. In the drawings, variations from the illustrated shapes may be expected as a result of, for example, manufacturing techniques and/or tolerances. Thus, the embodiments of the disclosure should not be construed as being limited to the particular shapes of regions illustrated herein but may include deviations in shapes that result, for example, from manufacturing processes.

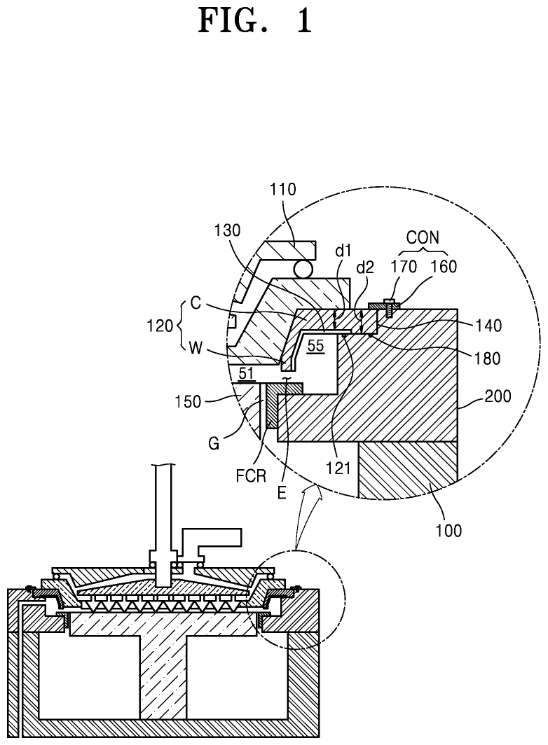

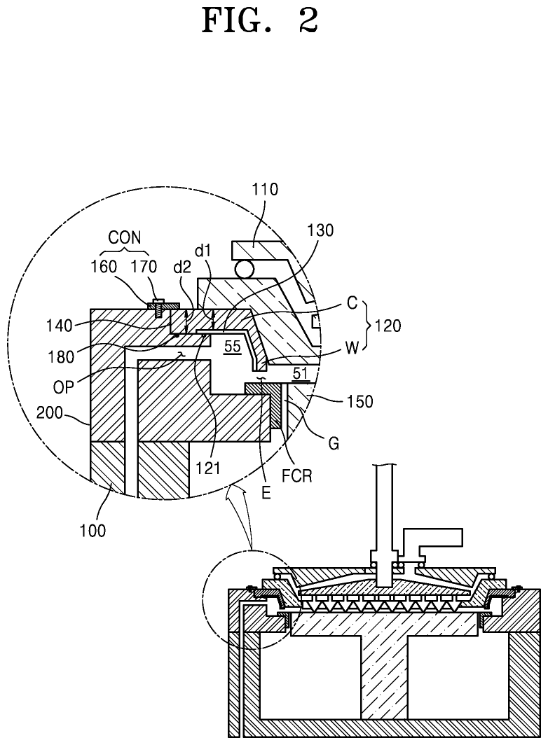

FIGS. 1 and 2 are views of a substrate processing apparatus according to embodiments of the inventive concept. FIG. 1 shows a substrate processing apparatus and a portion (a cross section of a portion where an opening of the support 200 is not formed) of the substrate processing apparatus. FIG. 2 shows a substrate processing apparatus and the other portion (a cross section of a portion where an opening OP of the support 200 is formed) of the substrate processing apparatus.

Referring to FIGS. 1 and 2, the substrate processing apparatus may include a substrate supporting unit 150, a processing unit 110, an exhaust unit 120, and a conductive extension 130. The substrate processing apparatus may include a reaction space 51 and an exhaust space 55 connected to the reaction space 51.

The processing unit 110 may be located on the substrate supporting unit 150 configured to support a substrate. The reaction space 51 may be defined between the substrate supporting unit 150 and the processing unit 110. The processing unit 110 may serve as a first lid that defines an upper surface of the reaction space 51. In other words, the first lid on the substrate supporting unit may include at least one processing unit 110.

The processing unit 110 may include members that perform appropriate functions depending on a function of the substrate processing apparatus. For example, when the substrate processing apparatus performs a deposition function, the processing unit 110 may include a reactant supplier (e.g., a showerhead assembly). In another embodiment, when the reactor performs a polishing function, the processing unit 110 may include a polishing pad.

The processing unit 110 may be a conductor and may be used as an electrode for generating plasma. That is, the processing unit 110 may serve as one electrode for generating plasma. The processing unit 110 in this manner (the manner in which the processing unit 110 is used as an electrode) is hereinafter referred to as a gas supply electrode.

The substrate supporting unit 150 may be configured to provide an area where an object to be processed (not shown) such as a semiconductor or a display substrate is seated. The substrate supporting unit 150 may be supported by a support (not shown) capable of vertical and rotational movement. Further, the substrate supporting unit 150 may be a conductor and may be used as an electrode for generating plasma (i.e., an opposite electrode of a gas supply electrode).

The exhaust unit 120 may be configured to define at least a portion of the exhaust space 55. The exhaust unit 120 may be located between the processing unit 110 and the support 200. The exhaust unit 120 may be implemented with a non-conductive material, for example, an insulator. On the other hand, the support 200 may be implemented with a conductive material, for example, a conductor. Therefore, a potential difference may be formed in the exhaust unit 120 arranged between the processing unit 110 serving as an electrode and the support 200 formed of a conductor, and the exhaust space 55 inside the exhaust unit 120. The potential difference may cause parasitic plasma, but as will be described later below, by introducing the conductive extension 130 inside the exhaust unit 120, the above-described potential difference may be eliminated, thereby preventing the generation of parasitic plasma.

In an embodiment, the exhaust unit 120 may serve as a second lid that defines a side surface of the reaction space 51. The second lid including the exhaust unit 120 may include the exhaust space 55 connected to the reaction space 51. Further, the exhaust unit 120 may provide a space in which the processing unit 110 is received. When the processing unit 110 is received in the space, the processing unit 110 may be in contact with the exhaust unit 120.

The exhaust unit 120 may include a partition wall W between the reaction space 51 and the exhaust space 55. A first surface (e.g., an outer surface) of the partition wall W may define the reaction space 51 and a second surface of the partition wall W (i.e., an inner surface as a surface opposite to the first surface) may define the exhaust space 55. For example, the reaction space 51 may be defined by the first surface side of the partition wall W, an upper surface of the substrate supporting unit 150, and a lower surface of the processing unit 110 which is the first lid.

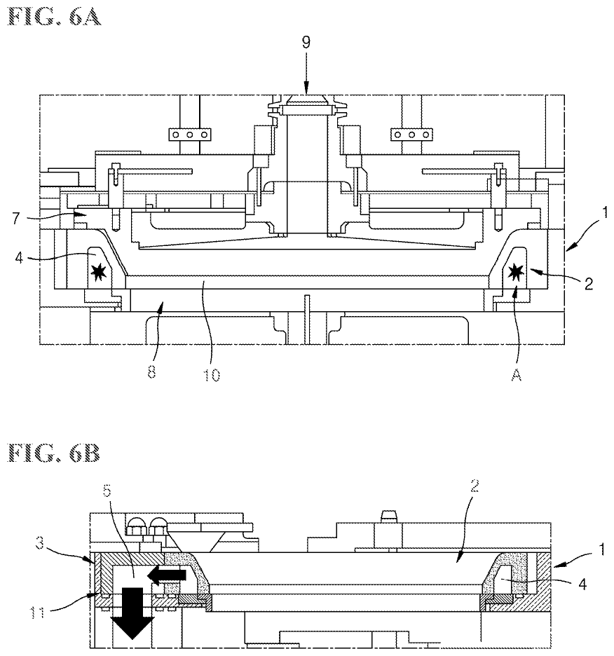

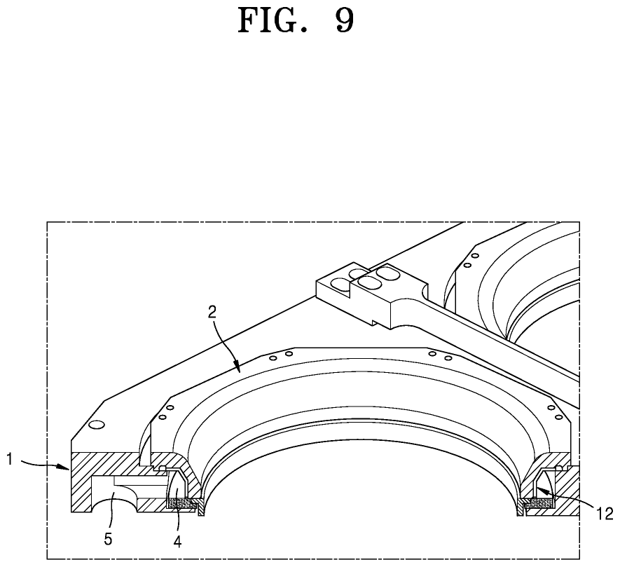

The exhaust unit 120 may further include a connecting wall C extending from the partition wall W. The connecting wall C may be configured to provide a contact surface with the processing unit 110. In more detail, an upper surface of the connecting wall C may contact the processing unit 110. In addition, a lower surface of the connecting wall C may contact the support 200. In more detail, the lower surface of the connecting wall C may be arranged to contact an upper surface of the seating portion 140 of the support 200. The support 200 may be a top lid 1 shown in FIG. 6 and FIG. 9

The exhaust unit 120 may provide a portion of a space for the object to be processed. For example, when the substrate processing apparatus performs a deposition function, the reaction space 51 for deposition may be defined by the exhaust unit 120. Further, the exhaust space 55 may be defined inside the exhaust unit 120. For example, the exhaust space 55 may be formed between the second lid including the exhaust unit 120 and the support 200. In more detail, a first side of the exhaust space 55 may be defined by the exhaust unit 120, and a second side (as opposed to the first side) of the exhaust space 55 may be defined by the support 200.

The conductive extension 130, together with a conductor of the support 200, may be configured to prevent parasitic plasma generated in the exhaust space 55. For example, the conductive extension 130 may be extended to surround at least a portion of the exhaust space 55 and may be grounded. Therefore, the exhaust space 55 may be surrounded by the conductive extension 130 and the conductive support 200, and accordingly, generation of parasitic plasma in the exhaust space 55 may be prevented.

The support 200 may contact the exhaust unit 120 to support the first lid including the processing unit 110 and the second lid including the exhaust unit 120. The support 200 may be supported by a partition 100. In this way, the support 200 may support the processing unit 110 serving as the first lid and the exhaust unit 120 serving as the second lid while being supported by the partition 100 to serve as a top lid covering an outer chamber. As described above, the support 200 may include a conductor.

The conductive extension 130 may be arranged to surround a portion of the second lid. The conductive extension 130 may extend along an inner surface of the partition wall W of the second lid and an inner surface of the connecting wall C. The conductive extension 130 may be electrically connected to the support 200. Therefore, the conductive extension 130 and the support 200 may have the same potential. In an embodiment, the conductive extension 130 may be implemented as a metal coating layer on a surface of the second lid. In another embodiment, the conductive extension 130 may be implemented as a metal plate having a certain thickness.

The conductive extension 130 may be arranged to contact the second lid. The second lid may include a first portion having a first thickness d1 and a second portion having a second thickness d2 greater than the first thickness. The connecting wall C of the second lid may include the first portion and the second portion. In this case, the sum of a thickness of the conductive extension 130 and the first thickness d1 of the first portion may be the same as the second thickness d2 of the second portion.

In some embodiments, at least one ring member may be inserted between the second lid and the support 200. The at least one ring member may include a conductive ring 121 and a sealing ring 180. The conductive ring 121 may be arranged between the conductive extension 130 and the support 200. In an example, the conductive ring 121 may be implemented as an elastic body having elasticity in a vertical direction. The elastic body may increase the adhesion between the conductive extension 130 and the support 200. The sealing ring 180 may be inserted between the second portion having the second thickness d2 of the second lid and the support 200. For example, the sealing ring 180 may include an O-ring.

The support 200 may be arranged between the partition 100 and a lid (e.g., the second lid including the exhaust unit 120). A gas flow control ring FCR may be on the support 200. In addition, the gas flow control ring FCR may be arranged between the support 200 and the substrate supporting unit 150. The gas flow control ring FCR may be slidably seated on the support 200. The gas flow control ring FCR may be apart from the substrate supporting unit 150 to form a gap G and a pressure balance between the reaction space 51 and an inner space of the outer chamber may be controlled by adjusting the gap G.

The partition wall W may provide a gap E connecting the reaction space 51 to the exhaust space 55. For example, the gap E may be formed between the exhaust unit 120 and the gas flow control ring FCR. The gap E may be a channel between the reaction space 51 and the exhaust space 55. Therefore, the reaction space 51 and the exhaust space 55 may communicate with each other through a channel under the partition wall W, and a gas in the reaction space 51 may be exhausted to the outside through the gap E serving as the channel, the exhaust space 55, and the opening OP.

Referring to FIG. 2 again, a portion of the second lid exhaust unit 120, which is the second lid, may communicate with the support 200. Therefore, a gas in the exhaust space 55 may be exhausted through the support 200. In an example embodiment, the support 200 may have an L-shaped or L-like shaped opening OP formed therein, so that a gas in the exhaust space 55 may flow laterally towards the support 200 and may be exhausted downward. In another example, the gas in the exhaust space 55 may flow laterally and may be exhausted upward. The gas exhausted through the support 200 may be exhausted to the outside by an exhaust pump (not shown).

The seating portion 140 may be formed on the support 200. The seating portion 140 may be on the opening OP through which a gas flows laterally. The seating portion 140 may provide a space in which the exhaust unit 120 is seated. In more detail, the second lid including the exhaust unit 120 may be arranged above the seating portion 140 of the support 200. In an example, the seating portion 140 of the support 200 may include a stepped structure. In this case, the second lid may be arranged to be inserted into the stepped structure.

In an alternative embodiment, in order to strengthen fixing force to the support 200 of the second lid, a connector CON may be arranged. The connector CON may be configured to connect the second lid to the support 200.

The connector CON may be implemented in various configurations. For example, the connector CON may include a lid portion 160 extending from an upper surface of the support 200 to an upper surface of the second lid. The lid portion 160 may be fixed to the support 200 by, for example, a fixing portion 170 implemented with a screw. By a configuration of the support 200 and the lid portion 160, a portion of the second lid may be arranged to be inserted into a space between the lid portion 160 and the support 200. Therefore, the second lid may be correctly fixed to the support 200.

Although the embodiments shown in FIGS. 1 and 2 are shown and described based on one reactor, the technical idea of the disclosure may be applied to a substrate processing apparatus including a plurality of reactors. For example, a substrate processing apparatus including four reactors shown in FIGS. 1 and 2 may be implemented.

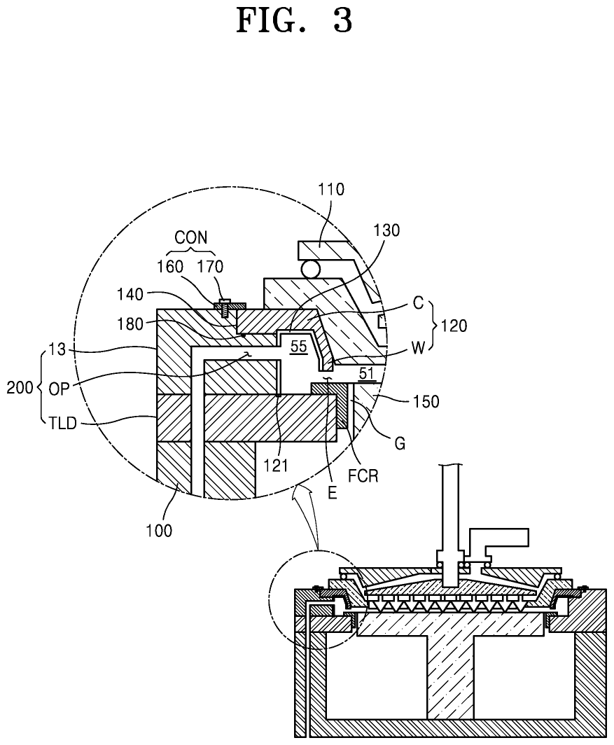

FIG. 3 is a view of a substrate processing apparatus according to other embodiments. The substrate processing apparatus according to these embodiments may be a modification of the substrate processing apparatus according to the above-described embodiments. Hereinafter, repeated descriptions of the embodiments will not be given herein.

Referring to FIG. 3, the support 200 of the substrate processing apparatus may include a top lid TLD and an exhaust port 13. It should be noted that in the embodiments of FIGS. 1 and 2, the top lid TLD and the exhaust port 13 are formed integrally, whereas in the embodiment of FIG. 3, the top lid TLD and the exhaust port 13 are separate components.

The exhaust port 13 may be stacked on the top lid TLD. The exhaust port 13 may be implemented with an insulator or a conductor. The exhaust port 13 shown in FIG. 3 is implemented with an insulator. In this case, in order to prevent the generation of parasitic plasma in the exhaust space 55, the conductive extension 130 may be arranged to further surround a side surface of the support 200, particularly a side surface of the exhaust port 13.

When the conductive extension 130 is arranged to surround a side surface of the exhaust port 13, the conductive ring 121 may be arranged in an area between the top lid TLD adjacent to an edge of the exhaust port 13 and the conductive extension 130. Accordingly, the conductive extension 130 and the top lid TLD are electrically connected to each other, so that a potential difference between the top lid TLD and the exhaust unit 120 may be eliminated.

Although not shown in the drawing, the exhaust port 13 may be implemented with a conductor. In this case, the conductive extension 130 will be similar to the configuration of FIG. 1. By implementing the exhaust port 13 in a separate configuration from the top lid TLD, maintenance of an L-like shaped opening OP in the exhaust port 13 may be more smoothly performed.

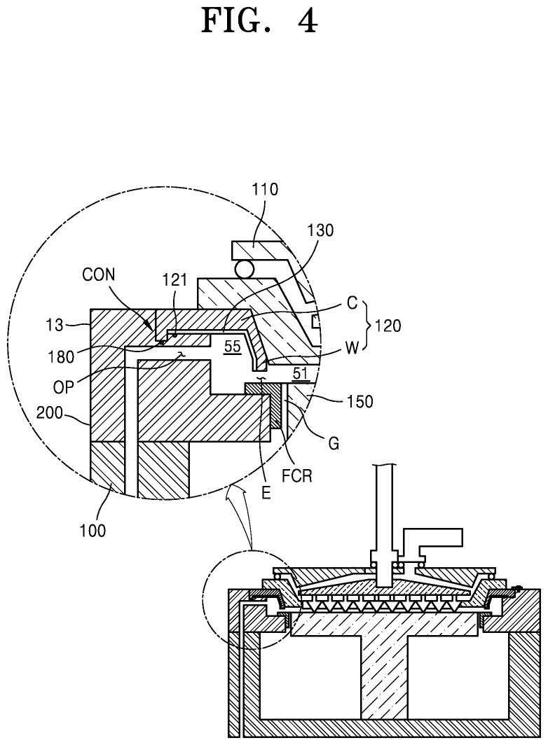

FIG. 4 is a view of a substrate processing apparatus according to other embodiments. The substrate processing apparatus according to these embodiments may be a modification of the substrate processing apparatus according to the above-described embodiments. Hereinafter, repeated descriptions of the embodiments will not be given herein.

Referring to FIG. 4, the connector CON provided to strengthen fixing force to the support 200 of the second lid may be implemented by the exhaust unit 120. In more detail, the exhaust unit 120 may further include a protrusion extending from the second lid, and the connection CON may include the protrusion. Alternatively, the connector CON may be a protrusion extending from the support 200 of the second lid, and the exhaust unit 120 may include a groove accommodating the protrusion.

In an embodiment, the protrusion may protrude from the connecting wall C of the second lid. For example, the connecting wall C may extend in a first direction, and the protrusion may protrude and extend in a second direction different from the first direction. The second lid may be detachably fixed to the support 200 by being arranged to be inserted into a groove provided in the support 200.

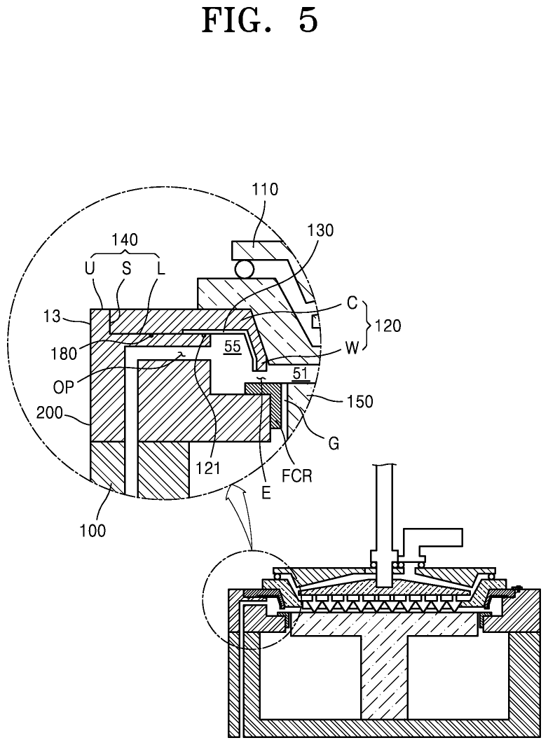

FIG. 5 is a view of a substrate processing apparatus according to other embodiments. The substrate processing apparatus according to these embodiments may be a modification of the substrate processing apparatus according to the above-described embodiments. Hereinafter, repeated descriptions of the embodiments will not be given herein.

It should be noted that in the above-described embodiments, a separate configuration (i.e., the connector CON) is introduced to connect the second lid to the support 200, whereas the substrate processing apparatus according to the embodiment in FIG. 5 does not have such a separate configuration. Referring to FIG. 5, by a self-load of the exhaust unit 120 and a contact structure between the exhaust unit 120 and a stepped structure, the second lid may be detachably fixed to a stepped structure of the support 200.

For example, the stepped structure included in the seating portion 140 of the support 200 may include a lower portion L, an upper portion U, and a side portion S connecting the lower portion L to the upper portion U. The lower portion L of the stepped structure may contact a lower surface of the exhaust unit 120. The side portion S of the stepped structure may contact a side surface of the exhaust unit 120. The second lid may be fixed to the support 200 by a frictional force generated by this contact and the mass of the support 200.

FIG. 6 is a view of a substrate processing apparatus according to related embodiments.

Referring to FIGS. 6A and B, a top lid 1 is equipped with a plurality of reactors, and each reactor includes a reaction space 10 consisting of a gas supply unit 7, gas exhaust units 2 and 3, and a substrate support 8. The gas supply unit 7 includes a conductive material, forms an upper surface of the reaction space 10, is arranged facing the substrate support 8, and supplies gas supplied through a gas inlet 9 to the reaction space 10. The gas exhaust units 2 and 3 include an exhaust duct 2 and an exhaust port 3, form a side portion of the reaction space 10, and exhaust gas in the reaction space 10 laterally. The exhaust duct 2 may be made of an insulator, for example a ceramic insulator such as Al₂O₃. The substrate support 8 is arranged facing the gas supply unit 7 and forms a lower surface of the reaction space 10. The substrate support 8 may be a heating block that mounts a processing substrate and heats the processing substrate. In FIG. 6A, at least one of the gas supply unit 7 and the substrate support 8 is connected to a high frequency power generator to function as a plasma electrode, and high-frequency power is supplied to a reactor through the gas supply unit 7 or the substrate support 8 to activate gas supplied to the reaction space 10 to generate plasma.

Meanwhile, when a plasma process is performed in the substrate processing apparatus, parasitic plasma may be generated outside the reaction space 10. For example, as a potential difference is formed between the gas supply unit 7 and the top lid 1 with an inner wall of the exhaust duct 2 as an insulator therebetween, parasitic plasma A may be generated in an inner space 4 of the exhaust duct 2. In this case, the exhaust duct 2 serves as a capacitor between two metal structures.

In addition, a potential difference is formed between the gas supply unit 7 and the top lid 1 with an outer wall of the exhaust duct 2 therebetween, and parasitic plasma may also be generated in an inner space of the exhaust port 3 made of Al, that is, an exhaust path 5. Therefore, a portion of applied high-frequency power may be lost, resulting in lower substrate processing efficiency and lower thin film properties.

In addition, the exhaust duct 2 is made of a ceramic material, which contributes to the increase and deformation of top lid weight, and is also a factor in the difficulty of processing and the increase in manufacturing cost due to the high degree of precision processing.

In addition, a mechanical connection between the exhaust duct 2 and the exhaust port 3, and a close contact portion between the exhaust port 3 and the top lid 1 have a possibility of gas leakage due to a machining error of the exhaust port 3 and a human error during fastening of the exhaust port 3.

The disclosure proposes an apparatus for preventing parasitic plasma from being generated in an area other than a reaction space during a plasma process. In more detail, the disclosure is to propose a reactor structure that prevents the generation of parasitic plasma in inner spaces of an exhaust duct and an exhaust port.

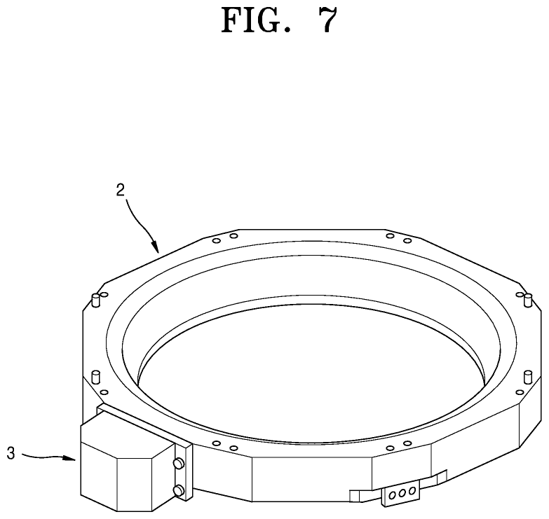

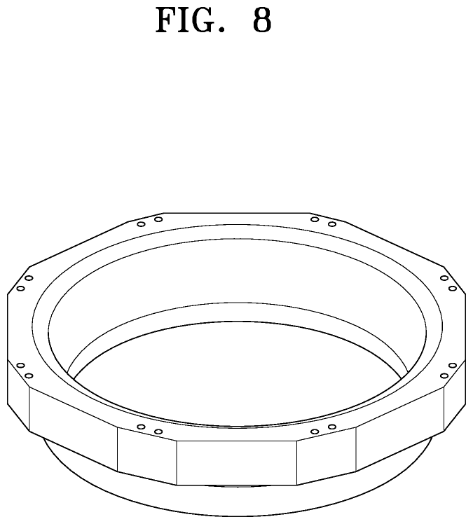

FIGS. 7 and 8 respectively show embodiments of an exhaust duct of the related art and an exhaust duct according to the disclosure.

The exhaust duct of FIG. 7 includes an inner surface, an outer surface, and an upper surface. In addition, the exhaust duct includes an inner space surrounded by the inner surface, the outer surface, and the upper surface, and an exhaust port 3 connected to a portion of the outer surface.

However, the exhaust duct of FIG. 8 according to embodiments of the inventive concept includes only an inner surface and an upper surface, and an outer surface, an inner space, and an exhaust port are not included.

FIG. 9 shows an embodiment of a reactor including the exhaust duct of FIG. 8.

Referring to FIG. 9, an exhaust duct (i.e., the exhaust duct of FIG. 8) according to embodiments of the inventive concept is installed on the top lid 1. The top lid 1 may be a support 200 shown in FIG. 1, FIG. 2, FIG. 4 and FIG. 5. In FIG. 9, an exhaust space 4 is defined by an inner wall of the exhaust duct 2 and an inner wall of the top lid 1 on which the exhaust duct 2 is arranged. Also, the exhaust port 3 (in FIG. 7) connecting the exhaust path 5 to the exhaust space 4 is removed and the exhaust path 5 and the exhaust space 4 are in direct communication.

An inner lid 12 shown in FIG. 9 is made of a conductive material and is installed in close contact with an inner surface of the inner wall of the exhaust duct 2. Then, the inner lid 12 and the top lid are connected to each other to have the same ground potential. Because formation of a space between the exhaust duct 2 and the inner lid 12 is suppressed, and the exhaust duct 2, the exhaust space 4, and the exhaust path 5 maintain the same potential as that of the top lid 1, there is a technical effect of suppressing generation of parasitic plasma in the exhaust space 4 and the exhaust path 5 even when high-frequency power is supplied to the reactor.

According to the disclosure, because the outer wall of the exhaust duct 2 and the exhaust port 3 are removed, there is a technical effect of removing the risk of leakage between the exhaust duct 2 and the exhaust port 3, and between the exhaust port 3 and the top lid 1 due to a machining error of the exhaust port 3. In addition, because the exhaust duct 2 is more simplified, the weight applied to the top lid 1 is reduced, and thus there is a technical effect of reducing deformation of the top lid.

According to the disclosure, the structure and shape of the exhaust duct 2 are simplified, thereby having a technical effect of reducing physical constraints for preventing the generation of parasitic plasma. For example, metal coating on the inner wall of the exhaust duct 2 may be made easier and the insertion of various devices such as a conductive inner lid may be made easier. In addition, as the manufacturing of the exhaust duct 2 becomes easier, the manufacturing cost may be reduced and the maintenance may be easier.

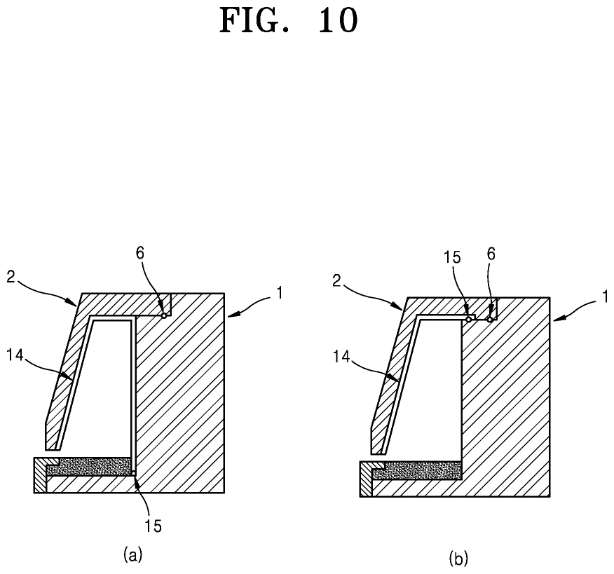

FIG. 10 shows a structure in which a potential difference between the inner lid 12 and the top lid 1 is the same.

Referring to FIG. 10, an O-ring 6 is arranged between the exhaust duct 2 and the top lid 1. In addition, a conductive inner lid 14 and the top lid 1 are connected to each other through a conductive ring 15 to have the same potential difference (ground level). The conductive ring 15 is preferably an elastic body having elasticity in a vertical direction. In addition, the conductive ring 15 has elasticity to increase adhesion between the inner lid 14 and the top lid 1. In the case of FIG. 10 (b), unlike FIG. 10 (a), the structure of the inner lid 14 may be further simplified. In addition, in consideration of a thickness of the inner lid 14, a portion of the exhaust duct 2 in close contact with the inner lid 14 may have a different thickness from that of a portion not in close contact with the inner lid 14 (see d1 and d2 in FIG. 1).

In another embodiment, instead of the conductive inner lid 14, the inner surface of the inner wall of the exhaust duct 2 is coated with a conductive material to further reduce the weight of the exhaust duct and make maintenance easier.

According to the embodiments described above, it is possible to suppress the generation of parasitic plasma in an exhaust duct and an exhaust path by simplifying a structure of the exhaust duct, thereby reducing the possibility of external leakage. In addition, the more simplified shape of the exhaust duct has a technical effect of reducing the deformation of a top lid by reducing the weight applied to the top lid.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate processing apparatus comprising:
a substrate supporting unit configured to support a substrate;
a first lid on the substrate supporting unit, the first lid comprising at least one processing unit;
a second lid under the first lid, the second lid comprising a partition wall; and
a support arranged under the first lid and the second lid and comprising an opening and a seating portion on the opening,
wherein the second lid is on the seating portion of the support.

2. The substrate processing apparatus of claim 1,
wherein a reaction space is formed between the substrate supporting unit and the processing unit, and
an exhaust space is formed between the second lid and the support.

3. The substrate processing apparatus of claim 2,
wherein a first surface of the partition wall defines the reaction space, and
a second surface of the partition wall defines the exhaust space.

4. The substrate processing apparatus of claim 3,
wherein the exhaust space is arranged to surround the reaction space,
a channel connecting the reaction space and the exhaust space is formed under the partition wall, and
a gas in the reaction space is exhausted to the outside through the channel, the exhaust space, and the opening.

5. The substrate processing apparatus of claim 1,
wherein the second lid is detachably fixed to the support.

6. The substrate processing apparatus of claim 5,
wherein the seating portion of the support includes a stepped structure, and
the second lid is arranged to be inserted into the stepped structure.

7. The substrate processing apparatus of claim 5, further comprising:
a connector configured to connect the second lid to the support.

8. The substrate processing apparatus of claim 7,
wherein the connector includes a lid portion extending from an upper surface of the support to an upper surface of the second lid, and
a portion of the second lid is arranged to be inserted into a space between the lid portion and the support.

9. The substrate processing apparatus of claim 7,
wherein the connector includes a protrusion extending from the second lid, and
the protrusion is arranged to be inserted into a groove provided in the support.

10. The substrate processing apparatus of claim 1,
wherein the second lid further comprises a connecting wall extending from the partition wall and providing a contact surface with the processing unit, and
a lower surface of the connecting wall is arranged to contact an upper surface of the seating portion.

11. The substrate processing apparatus of claim 1, further comprising:
a conductive extension arranged to surround a portion of the second lid.

12. The substrate processing apparatus of claim 11,
wherein the conductive extension is electrically connected to the support, and accordingly, the conductive extension and the support have the same potential.

13. The substrate processing apparatus of claim 11,
wherein the conductive extension is arranged to further surround a side surface of the support.

14. The substrate processing apparatus of claim 11,
wherein the conductive extension is implemented as a metal coating layer on a surface of the second lid.

15. The substrate processing apparatus of claim 11,
wherein the second lid includes a first portion having a first thickness and a second portion having a second thickness greater than the first thickness.

16. The substrate processing apparatus of claim 15,
wherein the conductive extension is arranged to contact the second lid, and
the sum of a thickness of the conductive extension and the first thickness is substantially the same as the second thickness.

17. The substrate processing apparatus of claim 1, further comprising:
at least one ring member arranged between the second lid and the support.

18. The substrate processing apparatus of claim 1,
wherein the second lid includes an insulator and the support includes a conductor.

19. A substrate processing apparatus comprising:
a substrate supporting unit configured to support a substrate;
a first lid on the substrate supporting unit, the first lid comprising at least one processing unit; and
a second lid under the first lid,
wherein a reaction space is formed between the substrate supporting unit and the processing unit,
an exhaust space is formed to surround the reaction space, and
a first side of the exhaust space is defined by the exhaust unit, and a second side of the exhaust space is defined by the support.

20. A substrate processing apparatus having an exhaust space,
the substrate processing apparatus comprising:
an exhaust unit defining at least a portion of the exhaust space;
a support configured to support the exhaust unit and comprising a conductor; and
a conductive extension arranged to surround a portion of the exhaust unit,
wherein the conductive extension, together with the conductor of the support, is configured to prevent parasitic plasma generated in the exhaust space.

21. The substrate processing apparatus of claim 12, further comprising:
a conductive ring between the conductive extension and the support.
